(19) United States
(12) Patent Application Publication
(10) Pub. No.: US 2014/0263947 A1
(43) Pub. Date: Sep. 18, 2014

(54) ENHANCED DYNAMIC RANGE IMAGING

(71) Applicants: Bart Dierickx, (US); CAELESTE CVBA, Antwerpen (BE)

(72) Inventor: Bart DIERICKX, Kontich (BE)

(73) Assignees: CAELESTE CVBA, Antwerpen (BE); Bart DIERICKX, Kontich (BE)

(21) Appl. No.: 13/833,664

(22) Filed: Mar. 15, 2013

(51) Int. Cl. H01L 27/146

(52) U.S. Cl. CPC H01L 27/146
USPC 250/206; 257/239

(57) ABSTRACT

A pixel element for an image sensor comprises a semiconductor substrate; a radiation-sensitive element configured to generate electric charges in response to incident radiation, and provided with a charge accumulation region configured to accumulate at least a portion of said electric charges; a passive potential barrier region; and a capacitive element operably connected to the charge-accumulation region of the radiation-sensitive element via the passive potential barrier region, the passive potential barrier region being configured to conduct charges from said charge accumulation region to the capacitive element when at least a predetermined amount of electrical charge has accumulated in said charge accumulation region.

### FIELD OF THE INVENTION

The present invention relates to the field of image sensors. More specifically it relates to an imaging pixel element and image sensor with such imaging pixel elements.

### BACKGROUND OF THE INVENTION

In many imaging applications, the image sensor needs to capture a high dynamic range (DR) of light intensities in an image. Classic image sensors have signal/noise ratio's (SNR) in the order of 1000:1 to 10000:1. When such sensor has a linear response, it can capture at most a dynamic range of a factor 10000:1 in light intensities. In order to increase the dynamic range of image sensors, many techniques are known in the art, which may use, for example, a non-linear response curve, e.g. multiple piece-wise linear slopes, logarithmic responses or log-lin responses, non-destructive readout, charge coupled devices (CCD) with two wells, overflow MOSFET capacitors, a combination of multiple shorter integration periods or smart reset pixels.

In U.S. Pat. No. 7,821,560, Sugawa et al. disclose a pixel structure comprising a photodiode, a transfer transistor coupled to the photodiode, and a plurality of capacitors for storing photocharges overflowing from the photodiode through the transfer transistor in storage operation. This “overflowing” implies a “storage gate” MOSFET between subsequent capacitance elements. In all drawings of the patent, Sugawa shows capacitors separated by storage gates. The overflow happens between storage capacitors over the storage gates.

In EP 2346079, Wang et al. disclose a pixel structure comprising a photo-sensitive element, a first transfer gate connected between the photo-sensitive element and a first charge conversion element. A second transfer gate is connected between the photo-sensitive element and a second charge conversion element. The use of multiple transfer gates requires an increased use of substrate area.

### SUMMARY OF THE INVENTION

It is an object of embodiments of the present invention to efficiently provide good imaging in an image sensor, more particularly imaging with high dynamic range.

The above objective is accomplished by a method and device according to embodiments of the present invention.

The present invention relates to a pixel element, an image sensor having such pixel elements, and a method to operate such pixel element.

In a first aspect, the present invention provides a pixel element for an image sensor. The pixel element comprises a semiconductor substrate; a radiation-sensitive element configured to generate electric charges in response to incident radiation, and provided with a charge accumulation region configured to accumulate at least a portion of said electric charges; a passive potential barrier region; and a capacitive element operably connected to the charge-accumulation region of the radiation-sensitive element via at least the passive potential barrier region, the passive potential barrier region being configured to conduct charges from said charge accumulation region to the capacitive element when at least a predetermined amount of electrical charge has accumulated in said charge accumulation region.

It is an advantage of embodiments of the present invention that simple and efficient means are provided for simultaneously obtaining multiple sensitivity ranges.

It is an advantage of using a passive potential barrier for overflowing charges that it is compact, and that no interconnections are required for controlling it.

It is an advantage of embodiments of the present invention that a high semiconductor fill factor can be obtained. It is also an advantage of embodiments of the present invention that multiple sensitivity ranges can be obtained without complex switch arrangements and the associated control signal infrastructure.

In the pixel element according to embodiments of the present invention, at least one electronic device may be operable coupled between the passive potential barrier and the capacitive element. The at least one electronic device may for instance be a switch for electrically decoupling the potential barrier region from the capacitive element. The at least one electronic elements may be coupled in series between the potential barrier region and the capacitive element. On top thereof, other electronic elements may be coupled in series between the potential barrier region and the capacitive element and/or other electronic elements may be coupled in parallel thereto.

In particular embodiments, the at least one electronic device may form anti-blooming circuitry, for preventing blooming.

In embodiments of the present invention, the potential barrier may be a two-terminal electrical device.

The passive potential barrier region may comprise a local geometrical restriction, a local dopant concentration variation and/or a local material composition variation in the semiconductor substrate. Alternatively, the passive potential barrier region may comprise a junction, a heterojunction, and/or a Schottky barrier. Yet alternatively, the passive potential barrier region may comprise a doped semiconductor resistor which may be a buried channel resistor. In particular embodiments, the passive potential barrier region may comprise an ion implanted region. In yet alternative embodiments, the passive potential barrier region may comprise a field-effect transistor, the gate of said field-effect transistor being connected to a substantially constant DC voltage supply.

In embodiments of the present invention, the radiation-sensitive element may comprise a photodiode. The photodiode may be a regular, hybrid or monolithic photodiode. Alternatively, the photodiode may be a pinned photodiode. In particular embodiments, the charge accumulation region may comprise a neutral zone in the pinned photodiode.

In embodiments of the present invention, the charge accumulation region may comprise a depletion region of the radiation-sensitive element.

A pixel element according to embodiments of the present invention may further comprise a floating diffusion for storing electrical charge generated in the pixel, and an output stage configured to generate a signal representative of the amount of electrical charge present on the floating diffusion. Such pixel element according may further comprise a merge switch configured to selectively open a conductive path between the capacitive element and the floating diffusion.

It is an advantage of embodiments of the present invention that a high dynamic range can be obtained by combining multiple sensitivity ranges.

It is a further advantage of embodiments of the present invention that the integration time of each sensitivity range is equal, thus that the high dynamic range may be obtained in just one precisely defined integration time, e.g. a predetermined integration time.

It is a further advantage of embodiments of the present invention that multiple sensitivity ranges may be obtained, each range having a substantially linear response. It is also an advantage that a gain factor may be implemented between each of these ranges, so that the ratio between the illumination level corresponding to saturation in the lowest gain range and the noise equivalent illumination level in the highest gain range, may correspond to a dynamic range that is much higher than each of the individual sensitivity ranges. While individual sensitivity ranges of 5000:1 may be provided, the combined sensitivity range can be in the order of 100000:1 or even more.

It is an advantage of embodiments of the present invention that a dynamic range of more than a ratio of 10000:1, or even in the order of 100000:1, in light intensities may be acquired in a single image frame.

A pixel element according to embodiments of the present invention may comprise a further output stage configured to generate a signal representative of the amount of electrical charge stored in the capacitive element.

In a pixel element according to embodiments of the present invention, the capacitive element may comprise a plurality of capacitive elements interconnected in series or in parallel. Such pixel element may then further comprise passive potential barriers connecting the plurality of capacitive elements.

A pixel element according to embodiments of the present invention may comprise a plurality of merge switches, each merge switch being configured to selectively open a conductive path between a corresponding capacitive element and a floating diffusion.

It is an advantage of embodiments of the present invention that a pixel element having a good dynamic range is provided.

It is an advantage of embodiments of the present invention that simultaneous measurements in multiple sensitivity ranges can be acquired efficiently in photometry.

It is an advantage of embodiments of the present invention that multiple sensitivity ranges can be combined to obtain a good dynamic range in photometry.

In a second aspect, the present invention provides an image sensor array comprising a plurality of pixel elements according to the first aspect of the present invention.

In a third aspect, the present invention provides a method for operating a pixel element according to the first aspect of the present invention. The method comprises:

during an exposure interval, accumulating electric charges generated by radiation incident on the pixel element in a charge accumulation region such that the electric charges in the charge accumulation region can overflow into a capacitive element over a passive potential barrier region when at least a predetermined amount of electrical charge has accumulated in said charge accumulation region, and

after said exposure interval, determining the amount of charge stored in the charge accumulation region during the exposure interval, and determining the amount of charge stored in at least the capacitive element during the same exposure interval.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 shows a pixel element according to a first embodiment of the present invention.

FIG. 2 shows a pixel element according to a second embodiment of the present invention.

FIG. 3 shows a pixel element according to a third embodiment of the present invention.

FIG. 4 shows a pixel element according to a fourth embodiment of the present invention.

FIG. 5 shows a semiconductor layout for a pixel element according to embodiments of the present invention.

FIG. 6 shows a potential diagram for an exposure phase of a pixel element according to embodiments of the present invention, under low light exposure conditions.

FIG. 7 shows a potential diagram for a readout phase of a pixel element according to embodiments of the present invention, under low light exposure conditions.

FIG. 8 shows a potential diagram for an exposure phase of a pixel element according to embodiments of the present invention, under high light exposure conditions.

FIG. 9 shows a potential diagram for a first readout phase of a pixel element according to embodiments of the present invention, under high light exposure conditions.

FIG. 10 shows a potential diagram for a second readout phase of a pixel element according to embodiments of the present invention, under high light exposure conditions.

FIG. 11 shows a potential diagram for a reset phase of a pixel element according to embodiments of the present invention.

FIG. 12 shows a first control pulse sequence diagram for a pixel element according to embodiments of the present invention.

FIG. 13 shows a second control pulse sequence diagram for a pixel element according to embodiments of the present invention.

FIG. 14 illustrates a pixel element according to a further embodiment of the present invention.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Throughout this description, the terms “horizontal” and “vertical”, “row” and “column” and related terminology are used to provide a coordinate system and for ease of explanation only. They do not need to, but may, refer to an actual physical direction of the device. Furthermore, the terms “column” and “row” are used to describe sets of array elements which are linked together. The linking can be in the form of a Cartesian array of rows and columns however the present invention is not limited thereto. As will be understood by those skilled in the art, columns and rows can be easily interchanged and it is intended in this disclosure that these terms be interchangeable. Also, non-Cartesian arrays may be constructed and are included within the scope of the invention. Accordingly the terms “row” and “column” should be interpreted widely. To facilitate in this wide interpretation, the claims refer to logically organised rows and columns. By this is meant that sets of array elements are linked together in a topologically linear intersecting manner; however, that the physical or topographical arrangement need not be so. For example, the rows may be circles and the columns radii of these circles and the circles and radii are described in this invention as “logically organised” rows and columns. Also, specific names of the various lines, e.g. reset line and first and second select line, are intended to be generic names used to facilitate the explanation and to refer to a particular function and this specific choice of words is not intended to in any way limit the invention. It should be understood that all these terms are used only to facilitate a better understanding of the specific structure being described, and are in no way intended to limit the invention.

Furthermore, as will be evident to the person skilled in the art, where in relation to embodiments reference is made p-type and n-type, positive and negative charge carriers, free electrons and holes, or similar terms related to electric charge polarity, it will be understood that these may merely refer to respectively a first and a second electrical charge sign and, for example, the associated majority carrier behaviours of materials. Such terms may therefore equally refer to the opposite charge polarity, insofar such charge sign reversal is consistently applied to the related structures.

In the context of the present invention, the impinging radiation may be electromagnetic radiation of any type, e.g. visible light, UV light, infra-red light, X-rays, gamma rays. Alternatively, the impinging radiation may be particles, including low or high energy electrons, protons, hadrons or other particles.

A potential barrier is the energy providing a repulsive force against the passage of an electron (or hole) through a region. In the context of the present invention, a passive potential barrier is a potential barrier formed by one or more passive devices or device features.

In a first aspect, the present invention relates to a pixel element for an image sensor. The pixel element comprises a semiconductor substrate. The pixel element also comprises a radiation-sensitive element for generating electric charges in response to incident radiation, e.g. the radiation-sensitive element is configured to generate electric charge in response to incident radiation. The radiation-sensitive element is provided with a charge accumulation region for accumulating at least a portion of these electric charges. Furthermore, a passive potential barrier region is provided, e.g. in the semiconductor substrate. The pixel element further comprises a capacitive element operably connected to the charge-accumulation region of the radiation-sensitive element through the passive potential barrier region. This passive potential barrier region is adapted for enabling a transfer of electric charge from the charge accumulation region to the capacitive element when at least a predetermined amount of electrical charge has accumulated in the charge accumulation region. For example, the passive potential barrier region may be configured to conduct charges from the charge accumulation region to the capacitive element when at least a predetermined amount of electrical charge has accumulated in the charge accumulation region.

A plurality of pixel elements according to embodiments of the present invention may be provided in an image sensor to obtain signals representative of a spatial distribution of a radiative quality over the image sensor. While each pixel element may be adapted to provide a local measure of a light quality, e.g. a light intensity, the present invention is not limited to photographic imaging or video recording in the visual light spectrum, but may also relate to imaging in the infrared, ultraviolet, X-ray or gamma range of the light spectrum, or even to detection of spatial distribution of other types of radiation, e.g. particle radiation, such as electron waves or proton waves. A plurality of pixel elements may be arranged in an array in an image sensor. For example, the pixel elements may be logically organised in rows and columns in an image sensor.

Referring to FIG. 1, a pixel element 10 for an image sensor according to a first embodiment of the present invention is shown. The pixel element 10 comprises a semiconductor substrate 11. The semiconductor substrate may be a p-type substrate, e.g. may be doped with p-type dopants to provide an excess of holes in the substrate.

The pixel element 10 comprises a radiation-sensitive element 12 provided in the substrate 11 for generating an electric charge in response to incident radiation, and provided with a charge accumulation region 13 for accumulating this electric charge. For example, the charge accumulation region 13 may be formed by an n-doped region embedded in a p-doped substrate 11.

The radiation-sensitive element 12 may comprise a photodiode, e.g. a regular photodiode, a hybrid photodiode or a monolithic photodiode. The radiation-sensitive element 12 may be a pinned photodiode (PPD). Alternatively, the photo-sensitive element 12 may for example comprise a metal-insulator-semiconductor structure forming a photogate. However, the present invention is not limited thereto, as it also applies to other radiation-sensitive elements 12, e.g. photoreceptors or radiation receptors that produce a current as function of the detected radiation, such as APDs, bolometers or photoresistors.

The charge accumulation region 13 may be formed by a depletion layer of the radiation-sensitive element 12 (in FIG. 1) or may be the neutral layer 13 of the pinned photodiode 12 (in FIG. 2).

The pixel element 10 further comprises a capacitive element 15. This capacitive element 15 is connected to the charge-accumulation region 13 through a passive potential barrier region 17 provided in the semiconductor substrate. This passive potential barrier region is configured to conduct electric charges from the charge accumulation region 13 to the capacitive element 15 when at least a predetermined amount of electrical charge has accumulated in the charge accumulation region 13, e.g. when a predetermined electrical potential level has been reached in the charge accumulation region 13, e.g. by photocharge accumulation. The capacitive element 15 can be implemented as an nMOS structure, e.g. implemented on the semiconductor substrate 11, which may be advantageously provided in a CMOS processing pipeline, yet other capacitive elements known to the person skilled in the art may be used, such as accumulation capacitors, metal-insulator-metal capacitors or metal fringe capacitors.

The passive potential barrier region 17 is a passive structure, in the sense that the predetermined amount of electrical charge to accumulate in the charge accumulation region 13 before conduction of charges from the charge accumulation region 13 to the capacitive element 15 is enabled, may be determined by design characteristics of the pixel element, as opposed to being actively controlled during operation. Therefore, embodiments of the present invention allow an advantageous distribution of charges in response to incident radiation over the charge accumulation region 13 and the capacitive element 15, without requiring additional complex infrastructure for control, e.g. control signal lines, control gates and control timing means. In particular embodiments, the charge storage capacity of the capacitive element 15 may be larger than the charge storage capacity of the charge accumulation region 13. Therefore, charges accumulated in the charge accumulation region 13 may correspond to a low intensity sensitivity range, while charges which overflowed into the capacitive element 15 may correspond to a high intensity sensitivity range.

The predetermined amount of electrical charge to accumulate in the charge accumulation region 13 may be below the full well capacity of the charge accumulation region, e.g. in the range of 75% to 99% of the full well capacity, e.g. at 95% of the full well capacity, or at 90% of the full well capacity. Here, full well capacity refers to the largest amount of charge that could be stored in the charge accumulation region 13, in the absence of the passive potential barrier region 17, before saturation occurs.

The passive potential barrier region 17 may comprise a local dopant concentration variation and/or a local material composition variation in the semiconductor substrate 11. The passive potential barrier region 17 may comprise an ion implanted region, e.g. a p-type and/or n-type implant in the substrate. Alternatively or additionally, the passive potential barrier region 17 may comprise a local geometrical restriction, e.g. may be formed by a narrowing of the channel from the charge accumulation region 13 to the capacitive element 15.

The passive potential barrier region 17 may comprise a junction, heterojunction, and/or a Schottky barrier. The passive potential barrier region 17 may comprise an implanted resistor and/or a buried channel resistor.

In alternative embodiments, the passive potential barrier region 17 may comprise a field-effect transistor, e.g. a MOSFET or JFET, in which the gate of this field-effect transistor is connected to a substantially constant voltage. While such arrangement would require a supply voltage, the passive potential barrier region 17 may still be considered a passive component, since the barrier does not require control signals and is substantially predetermined by design characteristics.

The pixel element 10 may also comprise an output stage 21 configured to generate a signal representative of the amount of electrical charge stored in the charge accumulation region 13. For example, the charge accumulation region 13, e.g. a floating diffusion region connected to the photosensitive element 12 or a depletion layer of the photosensitive element 12, may be connected to the gate of an output buffer amplifier, e.g. a charge to voltage amplifier such as a source follower. Before readout of the pixel element 10, the charge accumulation region 13 may be reset, i.e. emptied of non-equilibrium charge carriers, for example by operating a reset switch 22 which opens a conductive path from the charge accumulation region 13 to a reference voltage supply. During readout, the voltage in the charge accumulation region 13 may change due to charge accumulation, and this change may be amplified by the output buffer amplifier for readout.

The pixel element, according to embodiments of the present invention, may further comprise a merge switch 23 configured to selectively open a conductive path between the capacitive element 15 and the output stage 21. Thus, depending on the state of the merge switch 23, a voltage level representative of the amount of charge stored in the charge accumulation region 13 or a voltage level representative of the combined amount of charge stored in the charge accumulation region 13 and the capacitive element 15, may be acquired in the output stage.

Alternatively, in embodiments according to the present invention, the pixel element 10 may comprise a further output stage configured to generate a signal representative of the amount of electrical charge stored in the capacitive element 15. For example, the pixel element 10 may comprise a first output buffer amplifier for determining the charge stored in the charge accumulation region 13 and a second output buffer amplifier for the determining the charge stored in the capacitive element 15.

In embodiments of the present invention, as illustrated in FIG. 14, electronics devices may be present between the passive potential barrier region 17 and the capacitive element(s) 15. Such electronics devices may be placed in series (and/or in parallel) as illustrated in FIG. 14. The purpose of the electronics devices may for instance be to temporarily disconnect the radiation-sensitive element 12 from the capacitive element 15, e.g. for electronic shutter or anti-blooming purposes.

In the embodiment illustrated in FIG. 14, the electronics devices comprise a series switch, implemented in this embodiment as a MOSFET 140 for disconnecting the potential barrier region 17 and the radiation-sensitive element 12 from the capacitive element 15. Furthermore, a further MOSFET 141 can be provided e.g. for evacuating photocharges that would overflow the radiation-sensitive element 12 or the capacitive element 15. Such evacuation is generally known as “anti-blooming”. Switch 141 will be turned on when switch 140 is off, to ensure that all photocharge is evacuated (otherwise blooming risks to happen).

Referring to FIG. 2, in an embodiment of the present invention the output stage may also comprise a floating diffusion region 24, which may also be referred to as “sense node”, formed in or on the semiconductor substrate 11. Such floating diffusion region 24 may store charge for readout in the pixel element 10. The floating diffusion region 24 may be a region in an active substrate region, e.g. an active silicon (diffusion) region, electrically isolated from all other nodes, for example it may be a quasi-neutral region, e.g. which is not fully depleted, isolated by a p-n junction from other nodes. The floating diffusion region 24 may be separate from the radiation sensitive element 12 and may collect charges generated in the radiation sensitive element and transmitted through a conductive path between the radiation sensitive element and the floating diffusion region 24. Typically, there are no metal contacts to such region. Thus, its potential may be determined by the amount of charge stored in it, and its capacitance. Capacitance of this region is preferably very low, to achieve high conversion gain, e.g. to achieve a large change of its voltage with the addition of one electron. Such region is referred to as a floating diffusion region because, on one hand, this region may be located in Si diffusion, and on the other hand, the region is not connected to any of the fixed or controlled voltage nodes such that its potential may be considered to be “floating”, i.e. its potential level will vary depending on the amount of charge present on the node. Before readout, the floating diffusion region may be emptied of non-equilibrium charge carriers, i.e. may be reset. During the readout, the charges stored in the charge accumulation region 13 may be transferred to the floating diffusion region, e.g. by opening a transfer gate 25. In a further step of the readout, the charges stored in the capacitive element 15 and in the charge accumulation region 13 may together be read out by opening the merge gate 23. Or, the charges stored in the capacitive element 15 and in the charge accumulation region 13 may be read out separately by first reading out the charge accumulation region 13, pulsing the reset gate 22, and then reading out the capacitive element 15.

While in embodiments according to the present invention the output stage may comprise a floating diffusion region 24, in other embodiments the charge accumulation region may comprise a floating diffusion region operably connected to the radiation-sensitive element via a transfer gate.

In FIG. 3, another pixel element 30 according to embodiments of the present invention is shown. In the pixel element 30, the capacitive element may comprise a plurality of capacitive elements 15a, 15b interconnected in series or in parallel. The pixel element 30 may comprise a plurality of merge switches 23a, 23b. Each merge switch may be configured to selectively open a conductive path between a corresponding capacitive element 15a, 15b and the output stage 21.

FIG. 4 shows another such pixel element 30 according to embodiments of the present invention, where the capacitive element comprises a plurality of capacitive elements 15a, 15b, 15c. The pixel element 30 may optionally comprise further passive potential barriers 27ab, 27bc connecting the plurality of capacitive elements.

FIG. 5 illustrates an exemplary arrangement of a pixel element 10 according to embodiments of the present invention on a semiconductor substrate 11. A pinned photodiode may be formed in the substrate 11, such that, in a depletion zone thereof, the charge accumulation region 13 is provided. On a portion of the boundary of this depletion zone, the passive potential barrier region 17 is provided, for example by forming a geometrically constrained lateral channel. Alternatively, the passive potential barrier region 17 may be provided by a vertically oriented implant, e.g. in a direction orthogonal to the substrate surface. This passive potential barrier region 17 provides a constrained conductivity path, e.g. forms a potential barrier with respect to the potential well formed by the charge accumulation region 13, to the capacitive element 15, which may be an nMOS capacitor, or a metal plate capacitor or other types. This capacitor is connected via the merge gate 23 to a floating diffusion region 24, which may be connected to an output stage for readout. On a second portion of the boundary of the charge accumulation region 13, a transfer gate 25 may be provided for transferring charges in the charge-accumulation region 13 to the floating diffusion region 24 for readout.

Principles of operation of the pixel element according to embodiments of the present invention are illustrated with reference to the potential diagrams in FIG. 6 to FIG. 11. FIG. 6 shows how, in a low radiation intensity setting, charges accumulate in the charge accumulation region 42 during exposure 40. For example, photo- or particle-charge is integrated on a regular photodiode or pinned photodiode.

During charge integration, the photodiode junction potential drops by collecting electrons (for an n-type junction, as would equally apply to holes on a p-type junction). A low radiation intensity is in this irradiation setting insufficient to overcome the potential barrier 41 imposed by the passive potential barrier region.

During readout, shown in FIG. 7, the transfer gate is switched, such that potential barrier 44 imposed by the transfer gate is removed. The accumulated charges in the charge accumulation region 42 are transferred to a floating diffusion region 45, where a potential level generated by these charges may be measured by an output amplifier. This will yield a usable signal, since the charges did not overflow during integration, and a measure directly relatable to the incident radiation may be obtained.

FIG. 8 shows how, in a high radiation intensity setting, charges accumulate in the charge accumulation region 42 during exposure 40. Here, the high radiation intensity is sufficient to overcome the potential barrier 41 imposed by the passive potential barrier region. After collection of a predetermined amount of charges, the potential will drop below that of the barrier, and all further collected charges will overflow into the capacitive element, e.g. a capacitor. Thus, the excess charge 46 can transfer from the charge accumulation region to the capacitive element. Optionally this capacitor can overflow into a next capacitor (as illustrated in FIG. 3 and FIG. 4), or the capacitor can be segmented and have it contain the charge in all or parts of the segments.

During readout, shown in FIG. 9, the transfer gate is switched, such that potential barrier 44 imposed by the transfer gate is removed. The accumulated charges in the charge accumulation region 42 are transferred to a floating diffusion region 45, where a potential level generated by these charges may be measured by an output amplifier.

Since the photodiode overflowed during integration, there will be a finite signal to be read out from the capacitor. This signal can be read either by directly sensing the voltage on the capacitor node via a separate readout channel, or by tying, via a switch or a variable resistance or other methods known to the skilled in the art, the capacitor to the sense node for the classic readout.

For example, in a second readout phase, a merge gate 47 may be switched, as shown in FIG. 10, such that the voltage potential level of the floating diffusion region and the capacitive element may equalize. This allows a measurement by the output amplifier of the total charge. This way, by combining the first measurement and the second measurement, and applying suitable gain factors, the incident radiation during exposure may be simultaneously quantified in two substantially linear sensitivity ranges. Finally, as shown in FIG. 11, the pixel element may be reset by switching a reset gate 49, while maintaining the merge gate in open state. This way, non-equilibrium charges may be evacuated from the floating diffusion and the capacitive element, such that the pixel, after closing merge gate, transfer gate and reset gate, is in a state to capture a new exposure.

Thus, multiple ranges are obtained by overflowing of charges from the charge accumulation region into one or more capacitive elements over one or more passive potential barriers, which each can be read via a single sensing node, e.g. via the same floating diffusion as for the photodiode, or via a different path, e.g. multiple parallel output stages. The first range may be the photocharge that is collected in the photodiode and may be read out on a floating diffusion, as known by people skilled in the art. The second range is the charge that was too large to be contained in the photodiode and that was overflowed during the integration time and thus not read out in the “first range” signal. Yet, it can be read out separately by a separate sense amplifier, or by the same sense amplifier which reads the first range by connecting it there via a switch. Beyond the second range there can be a 3rd range etc. that can be implemented by various methods known to people skilled in the art, such as by another overflow barrier and capacitors.

An exemplary control pulse sequence for a pixel element comprising a single capacitive element is shown in FIG. 12, showing the activation 61 of the transfer gate after an exposure period 60. After transfer of the charges in the charge accumulation region to the floating diffusion region FD, a voltage difference R1−S1 may be measured representative of the amount of charge accumulated in the charge accumulation region during exposure. Then, the merge gate may be activated 62, thereby switching the capacitive element, or a floating diffusion region FD2 associated therewith, in parallel to the floating diffusion region FD. Thus, a second voltage difference R2−S2 may be measured representative of the amount of charge accumulated in both the charge accumulation region and the capacitive element during exposure.

Referring to FIG. 13, another exemplary control pulse sequence is shown for a a pixel element having multiple capacitive elements. Here, a reset pulse is generated while all merge gates are open. Then, each merge gate is turned off in sequence, while obtaining a reference potential for the floating diffusion FD in each step. After all merge gates are switched off, the pixel is exposed during an exposure time interval 60. Subsequently, measurements S1, S2, S3, S4 may be obtained corresponding to the plurality of sensitivity ranges by activating the merge gates in sequence.

In preferred embodiments, the charge capacity of the capacitive element may be larger than that of the charge accumulation region, e.g. than the capacity of the photodiode, so that the ranges are clearly different and that combination of these ranges may result in a significant increase of the combined dynamic range, e.g. to provide the capability of charge-to-voltage-conversion of a large range of photo charges to a usable voltage signal.

In a second aspect, the present invention relates to an image sensor array comprising a plurality of pixel elements according to the first aspect of the invention, e.g. such pixel elements logically arranged in rows and columns, e.g. such that a two-dimensional image may be constructed composed of individual localized radiation measurements.

In a further aspect, the present invention relates to a method for reading out a pixel element according to the first aspect of the present invention. The method comprises, during an exposure interval, e.g. an exposure time interval, accumulating electric charges generated by radiation incident on the pixel element in a charge accumulation region such that the electric charges in the charge accumulation region can overflow over a passive potential barrier into a capacitive element when at least a predetermined amount of electrical charge has accumulated in said charge accumulation region. The method further comprises, after this exposure interval, determining the amount of charge stored in the charge accumulation region, and determining the amount of charge stored in at least the capacitive element. Both the charge stored in the charge accumulation region and the charge stored in at least the capacitive element are related to the same integration period.

1. A pixel element for an image sensor, the pixel element comprising:
a semiconductor substrate,
a radiation-sensitive element configured to generate electric charges in response to incident radiation, and provided with a charge accumulation region configured to accumulate at least a portion of said electric charges,
a passive potential barrier region, and
a capacitive element operably connected to the charge-accumulation region of the radiation-sensitive element via at least the passive potential barrier region, the passive potential barrier region being configured to conduct charges from said charge accumulation region to the capacitive element when at least a predetermined amount of electrical charge has accumulated in said charge accumulation region.

2. The pixel element according to claim 1, in which the potential barrier is a two-terminal electrical device.

3. The pixel element according to claim 1, wherein at least one electronic device is operable coupled between the passive potential barrier and the capacitive element.

4. The pixel element according to claim 3, wherein the at least one electronic device forms anti-blooming circuitry.

5. The pixel element according to claim 1, in which said passive potential barrier region comprises a local geometrical restriction, a local dopant concentration variation and/or a local material composition variation in the semiconductor substrate.

6. The pixel element according to claim 1, in which said passive potential barrier region comprises a junction, a heterojunction, and/or a Schottky barrier.

7. The pixel element according to claim 1, in which said passive potential barrier region comprises a doped semiconductor resistor which may be a buried channel resistor.

8. The pixel element according to claim 1, in which said passive potential barrier region comprises a field-effect transistor, the gate of said field-effect transistor being connected to a substantially constant DC voltage supply.

9. The pixel element according to claim 1, in which said radiation-sensitive element comprises a photodiode.

10. The pixel element according to claim 9, in which said photodiode is a regular, hybrid or monolithic photodiode.

11. The pixel element according to claim 9, in which said photodiode is a pinned photodiode.

12. The pixel element according to claim 11, in which said charge accumulation region comprises a neutral zone in the pinned photodiode.

13. The pixel element according to claim 1, in which said charge accumulation region comprises a depletion region of the radiation-sensitive element.

14. The pixel element according to claim 1, further comprising a floating diffusion for storing electrical charge generated in the pixel, and an output stage configured to generate a signal representative of the amount of electrical charge present on the floating diffusion.

15. The pixel element according to claim 14, further comprising a merge switch configured to selectively open a conductive path between the capacitive element and the floating diffusion.

16. The pixel element according to claim 14, comprising a further output stage configured to generate a signal representative of the amount of electrical charge stored in the capacitive element.

17. The pixel element according to claim 1, in which the capacitive element comprises a plurality of capacitive elements interconnected in series or in parallel.

18. The pixel element according to claim 17, comprising further passive potential barriers connecting the plurality of capacitive elements.

19. The pixel element according to claim 18 and claim 15, comprising a plurality of merge switches, each merge switch being configured to selectively open a conductive path between a corresponding capacitive element and a floating diffusion.

20. An image sensor array comprising a plurality of pixel elements according to claim 1.

21. A method for operating a pixel element according to claim 1, the method comprising:
during an exposure interval, accumulating electric charges generated by radiation incident on the pixel element in a charge accumulation region such that the electric charges in the charge accumulation region can overflow into a capacitive element over a passive potential barrier region when at least a predetermined amount of electrical charge has accumulated in said charge accumulation region, and
after said exposure interval, determining the amount of charge stored in the charge accumulation region during the exposure interval, and determining the amount of charge stored in at least the capacitive element during the same exposure interval.
